(19) United States
(12) Patent Application Publication
(10) Pub. No.: US 2002/0138225 A1
(43) Pub. Date: Sep. 26, 2002

(54) Automatic configuration of delay parameters for memory controllers of slave processors

(76) Inventors: Isaac H. Wong, Fremont, CA (US); Ka-Pui Ko, Milpitas, CA (US)

Correspondence Address: Jon W. Hallman, SKJERVEN MORRILL MacPHERSON LLP, 25 Metro Drive, Suite 700, San Jose, CA, 95110-1349, US

(21) Appl. No.: 09/772,113

(22) Filed: Jan. 25, 2001

(51) Int. Cl. G06F 19/00; G01R 27/28; G01R 31/00; G01R 31/14

(52) U.S. Cl. 702/119

(57) ABSTRACT

A method for automatically selecting delays for slave processors' memory controllers in a multiprocessor system is presented. A master processor coupled to the slave processors on a bootstrap bus commands the slave processors' memory controllers to select the delays. Various delay parameters are tested to select optimal delay parameter values.

### RELATED APPLICATIONS

This application is related to “Automatic Configuration of Delay Parameters in a Dynamic Memory Controller,” concurrently filed herewith, and “A System of Connecting Multiple Processors in Cascade,” concurrently filed herewith, the contents of both of which are incorporated by reference herein in their entirety.

### FIELD OF THE INVENTION

The present invention relates generally to the field of initializing delay values for memory controllers within a multiprocessor system. More specifically, the present invention relates to methods and apparatus for automatically setting delay values in memory controllers for slave processors in a multiprocessor system.

### DESCRIPTION OF RELATED ART

Co-pending U.S. application “A System of Connecting Multiple Processors in Cascade” describes a system for initializing slave processors under the control of a master processor in a multiprocessor system. Using a “bootstrap interface,” the master processor transfers boot code to SDRAM devices of the slave processors. Because this transferred boot code is stored in their SDRAM devices, the slaves need not have dedicated boot ROM devices, minimizing memory costs and hardware.

However, memory controller must coordinate their communication with SDRAM devices according to two delays. One delay relates to when the memory controller transmits a clock signal to the SDRAM device. A second delay relates to when the memory controller latches data received from the SDRAM device. The two delays form a delay pair. Thus, the memory controllers for the slave processors' SDRAM devices require proper initialization of this delay pair before the boot code can transferred to the SDRAM devices by the master processor. Typically, a user must manually initialize the delay pair, requiring a laborious laboratory exercise. To alleviate the need for this manual process, automated methods of initializing the delay pair have been developed as described in U.S. Pat. No. 6,137,734. In an automated system, a choice must be made for the optimal setting of the delay pair. A robust algorithm for the optimal selection of the delays is disclosed in copending U.S. application “Automatic Configuration of Delay Parameters in a Dynamic Memory Controller.” As used herein, this robust algorithm shall be denoted an “edge avoidance” algorithm because it ensures selection of a delay operating point remote from marginal delay operating points. In such marginal operating points, small errors induced by, for example, aging or temperature changes may cause memory controllers using delays having these marginal operating values to fail to communicate properly with their SDRAM devices.

Accordingly, there is a need in the art for a master/slave multiprocessor system in which the master processor automatically initializes, through the bootstrap interface, the delay values for the slave's memory controllers using the edge avoidance algorithm.

### SUMMARY

In accordance with the present invention, a method is provided for automatically selecting the delay pairs used to configure for the memory controllers of slave processors in a multiprocessor system. The multiprocessor system couples a master processor to the slave processors through a bus. The master processor commands the selection of delays for configuring the slave memory controllers using the bus. Various delays are tested by whether the slave processors boot successfully using boot code transferred over the bootstrap bus. From the delays for which the slave processors booted successfully, an optimal selection of delays is made by the master processor.

### BRIEF DESCRIPTION OF THE DRAWINGS

FIG. 1 illustrates a master/slave bootstrap architecture according to one embodiment of the invention.

FIG. 2 illustrates, for the master processor and one slave processor from FIG. 1, the arrangement of the cascade bootstrap interface modules.

FIG. 3 illustrates a memory mapping using a single chip-select.

FIG. 4 illustrates a memory mapping using two chip-selects.

FIG. 5 illustrates a timing diagram for the signals carried on the bootstrap bus according to one embodiment of the invention.

FIG. 6a is a shmoo plot for the delay parameters used by a memory controller according to one embodiment of the invention.

FIG. 6b illustrates the circle of largest radius within the shmoo plot of FIG. 6a.

FIG. 8 is a flowchart illustrating an algorithm for dividing shmoo plot values into boundary and non-boundary sets according to one embodiment of the invention.

Use of the same reference symbols in different figures indicates similar or identical items.

### DETAILED DESCRIPTION

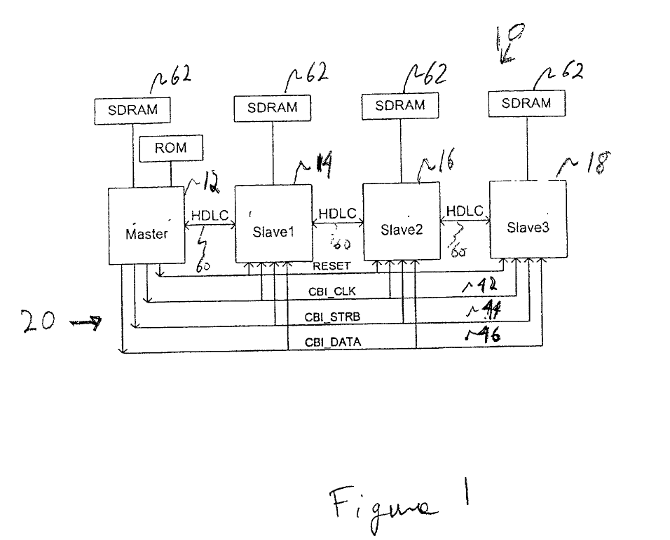

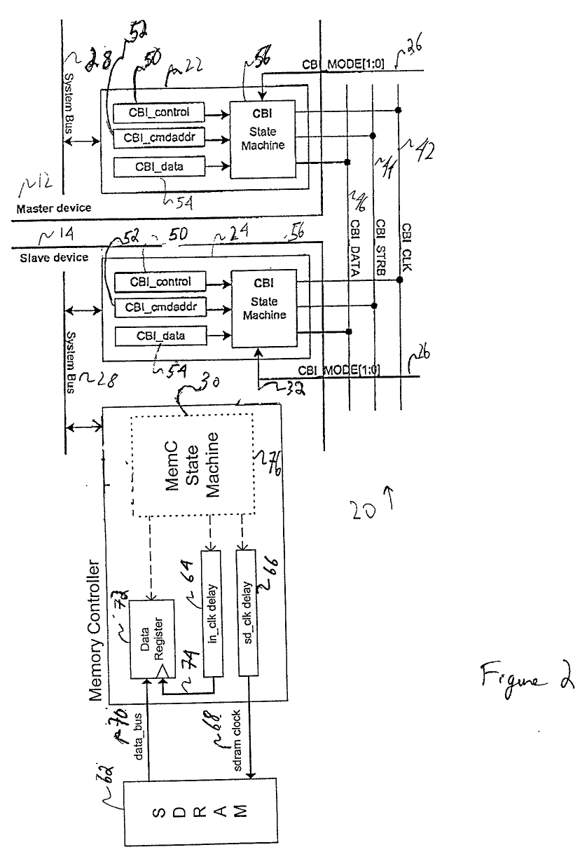

Referring now to FIGS. 1 & 2, a master/slave architecture 10 for implementing one embodiment of the invention is illustrated. A master processor 12 has both a ROM device and a synchronous-dynamic RAM device (SDRAM) 62. Using the ROM device, the master processor 12 may boot-up in a conventional fashion. However, slave processors 14, 16, and 18 do not have ROM devices for storing boot code. Thus, these processors cannot boot in a conventional manner. Instead, their boot code will be transmitted by the master processor 12 to the individual slave processors over a bootstrap bus 20. In addition to transmitting the boot code, the bootstrap bus 20 is also used to transmit delays for configuring the delay buffers 64 and 66 of a memory controller 30 associated with the slave processors.

Each memory controller 30 controls its SDRAM device 62. To permit the SDRAM device 62 to synchronize with a system clock used in the memory controller 30, the memory controller 30 delays the system clock signal according to a delay buffer 66 to produce an SDRAM clock signal 68. The SDRAM device 62 returns a data signal corresponding to memory request to the memory controller 30 on a data bus 70. To synchronize the latching of this data signal in a data register 72, the memory controller uses the delay buffer 64 to delay its system clock to produce a data latch input clock 74. For convenience, the amount of delay produced at the delay buffer 66 may be denoted as the SDRAM clock delay (SD_CLK) or tap value, whereas the amount of delay produced at delay buffer 64 may be denoted as the in clock delay (IN_CLK) or tap value. A state machine 76 controls the IN_CLK and SD_CLK tap values as well as the operation of the data register 72. This state machine 76 is in turn under the control of the master processor 12 as will be discussed further herein. The master processor will use the bootstrap bus 20 to write to control registers of the state machine 76 to select IN_CLK and SD_CLK values according to the edge avoidance algorithm.

The processors couple to the bootstrap bus 20 through a bootstrap interface module. The details of the bootstrap interface module will be discussed further below. To minimize hardware requirements, the communication over bootstrap bus 20 may be one-way: from the master processor 12 to the slave processors. Thus, the master bootstrap interface module 22 is shown transmitting signals to the bootstrap bus 20, whereas the slave bootstrap interface module 24 is shown receiving signals from the bootstrap bus 20.

Although the hardware in the bootstrap interface modules 22 and 24 may be specialized for either a master or a slave role, a bootstrap interface module must identify its role upon power-up to permit a generic construction for either role. A generic construction provides a user flexibility in assigning slave and master roles to processors. In a generic construction, the bootstrap interface module doesn't know at power-up whether it is a slave or a master. Thus, the bootstrap interface module receives an identification signal 26 indicating its role as either master or slave. Because there is only one master processor, only a single type of “master” identification signal need be provided. However, because an arbitrary plurality of slave processors may require different boot codes, each slave processor should be uniquely identified. The number of bits in the identification signal 26 should be adequate to support uniquely identifying each slave. For example, in an embodiment of the invention having four slave processors, the identification signal should be two bits to uniquely identify the master and the three slaves. For such an embodiment, the identification signal 26 may couple to the bootstrap interface module through two pins (not illustrated) of the integrated circuit containing the device. The pins would either be grounded or brought high to identify the bootstrap interface module.

At power-up, a bootstrap interface module receives the identification signal 26 and determines its role. Each bootstrap interface module couples to a system bus 28 so that the module may configure a memory controller 30 within the respective processors. Should the bootstrap interface module be a slave bootstrap interface module 24, it configures its memory controller 30 to deny processor memory requests. On the other hand, should the bootstrap interface module be a master bootstrap interface module 22, it configures its memory controller 30 to accept processor memory requests. Only minor modifications/extensions to a typical memory controller design are necessary to permit a bootstrap interface module to configure the memory controller. Because MIPS-based processors are popular in networking applications and often used in a multiprocessor configuration, the modifications and following description will address a MIPS environment. However, the principles of the invention are readily adaptable for other types of processors.

The memory controller used in the invention supports multiple client modules (not illustrated). These client modules include embedded CPU cores, DSP and I/O peripheral modules. The client modules submit requests to the memory controller 30 when they require memory read/write accesses to external memory. The memory controller 30 has a memory-request-enable register (MEM_REQ_EN) (not illustrated). This register is part of the mechanism by which memory requests by the client modules can be enabled or disabled. Each client module has a bit in the MEM_REQ_EN register associated with it. The memory controller 30 allows memory access by those client modules whose enable bit in the MEM_REQ_EN register is set to logical “1.” If the enable bit is set to logical “0,” the memory controller 30 denies memory access from that client module. For the master processor 12, the bits in the MEM_REQ_EN register are set to all 1's on power-up, allowing the request by its embedded CPU to fetch the boot code from its ROM device. For the slave processors, the bits in the MEM_REQ_EN register are set to all 0's except for the enable bit of the slave bootstrap interface module 24. This bit setting blocks any memory requests by the embedded CPUs in the slave processors, preventing the slave CPUs from fetching their boot code. After the master processor has finished downloading the boot code into the slave processors' SDRAM devices, the bits in the MEM_REQ_EN register may be set to all 1's to enable memory accesses, for example, by the slave processors' CPUs. Note that the embedded CPU core in the slave processor requires no modification in its boot mechanism (as defined by its hardware and software). Indeed, as far as the slave processor is concerned, it is booting normally. The embedded CPU core in a slave processor has no knowledge that its request for boot code is being blocked (delayed) while the boot code is being downloaded into its external memory by the master processor. This is advantageous because changes to the CPU boot mechanism are typically difficult and expensive to implement.

The memory controller 30 may support up to 8 external memory devices. When the memory controller 30 needs to access a particular external memory device it asserts a chip-select (CS) signal coupled to that memory device. The memory controller 30 has 8 memory base address and mask registers (MEM_BA) (not illustrated), each associated with a respective chip-select signal. The MEM_BA registers define the base address and size of the external memory devices. By using the values programmed into these MEM_BA registers, the memory controller 30 determines which external memory device contains the address requested by a client module such as the processor's embedded CPU. Thus, given a particular memory request, the MEM_BA registers determine which chip-select to use. For the master processor 12, two of these MEM_BA registers will be set, on power-up, to default values. One of these MEM_BA registers allows the MIPS boot address 0×1fc0_{—}0000 to be mapped to the master's ROM device. Similarly, the starting address of the interrupt/exception handler is 0×0000_{—}0080 in a MIPS processor. The remaining MEM_BA register maps this memory request to the master processor's SDRAM device. For the slave processors 14, 16, and 18, the master processor sets corresponding MEM BA registers using the bootstrap interface modules and the bootstrap bus 20.

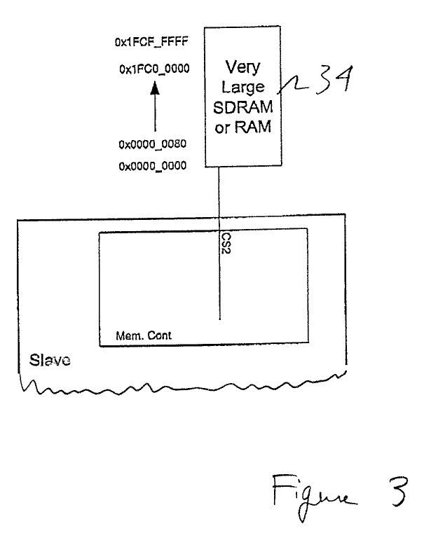

When a MIPS processor executes an interrupt it will always branch to the address of the interrupt/exception handler, which is 0×0000_{—}0080 as defined by the MIPS architecture. The starting address of the boot code in ROM is very different: 0×1fc0_{—}0000. If both the starting boot code address and the interrupt/exception handler address are mapped using a single chip-select (e.g., CS2) and its MEM_BA register, a very large SDRAM device 34 is required as seen in FIG. 3. This SDRAM device 34 must allow for gigabytes of storage to cover the large range between these addresses. Although this is feasible, it requires an unnecessarily large SDRAM device 34 that may be very expensive.

A preferred solution for the slave processors configures their memory controllers to internally OR two separate chip-selects onto a single output pin. The MEM_BA registers corresponding to the two chip-selects are configured such that the starting ROM address and the exception/interrupt handler address map to the same address space in the SDRAM device 62. For example, chip-select 2 (CS2) and chip-select 7 (CS7) could both be ORed to a single output pin coupled to the slave processor's SDRAM device 62. Accordingly, the master processor 12 configures the corresponding MEM_BA registers, MEM_BA2 and MEM_BA7, appropriately using the bootstrap interface modules 22 and 24 and the bootstrap interface bus 20. An understanding of the appropriate configuration of these registers requires a discussion of their respective bit fields.

The MEM_BA2 register's bit field is defined as:

| Bit Field | Description | R/W | default |
|---|---|---|---|
| 0 | Valid bit for CS2 | R/W | 0 |
| 9:1 | Address Mask [31:23] for CS2 | R/W | |
| 18:10 | Base Address [31:23] for CS2 | R/W | |

Similarly, the MEM_BA7 register's bit field is defined as:

| Bit Field | Description | R/W | default |
|---|---|---|---|
| 0 | Valid bit for CS7 | R/W | 0 |
| 12:1 | Address Mask [31:20] for CS7 | R/W | |
| 24:13 | Base Address [31:20] for CS7 | R/W | |

Note that the base address and mask values define only the upper bits of their 32-bit values. The lower bits are assumed to be zero. For example in the MEM_BA2 register, setting the address mask value to 0×1ff actually indicates a 32-bit mask value of 0×ff80_{—0000} because this mask value represents only bits 23 through 31 of the full 32-bit address mask. Mapping both the starting address of the exception/interrupt handler and the starting address of the ROM boot code to the same address space requires that the base address and mask values be configured by the master processor as follows:

| Bit Field | Value | Description |
|---|---|---|
| MEM_BA2:address mask | ′b1111_1111_1 | For phy.Address |
| | | 0x0000_0000 and up |
| MEM_BA2:base address | ′b0000_0000_0 | For phy.Address |
| | | 0x0000_0000 and up |
| MEM_BA7:address mask | ′b1111_1111_1111 | For phy.Address |
| | | 0x1fc0_0000 and up |
| MEM_BA7:base address | ′b0001_1111_1100 | For phy,Address |
| | | 0x1fc0_0000 and up |

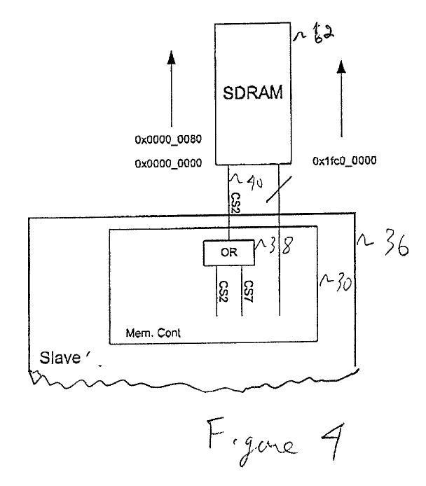

Referring now to FIG. 4, the resulting mapping is illustrated. Bootstrap memory requests from the master processor 12 are mapped to CS7 by the memory controller 30. Note that as used herein, a “memory request shall denote either a read request or a write request. After the slave processor has booted, its processor memory requests are mapped to CS2 by the memory controller 30. These two chip-selects are internally ORed at OR gate 38 onto the external CS2 pin 40. This pin couples to the SDRAM device 62. Note the marked savings in memory over the embodiment of the invention illustrated in FIG. 3 because the address space for boot code, starting at 0×1fc0_{—}0000 overlaps with the address space for operating RAM storage starting at the interrupt/exception handler address of 0×0000_{—}0080. A block of memory starting at 0×0000_{—}0080 is reserved for the exception/interrupt handler. In one embodiment of the invention, the address range below the MIPS exception vector address 0×0000_{—}0080 (0×0000_{—}0000 through 0×0000_{—}007F) stores the beginning segment of the boot code for the slave processor. This segment of the boot code typically contains a branch instruction to branch to other segments of the boot code located at other memory locations.

If a generic construction is desired for the memory controller 30 for both master and slave processors, the OR gate for the two chip-selects may be made configurable. A default programming value would disable the configurable OR gate such that the master processor's memory controller would not OR any chip-select signals. During the configuration of the slave processor's memory controller 30 by the master processor 12, the configurable OR gate would not be disabled so the appropriate chip-select signals are ORed. Alternatively, a generic construction for the memory controllers may be avoided by simply permanently ORing the appropriate chip-selects in the slave processors' memory controllers.

The cascade bootstrap bus 20 may consist of only three lines: a line 42 for carrying the bootstrap clock, a line 44 for carrying the bootstrap strobe, and a line 46 for carrying the bootstrap data signal. These signals are propagated in a one-way fashion from the master processor 12 to the slave processors 14, 16, 18, acting to send a 32-bit address/command word and a 32-bit data word sequentially on the data signal line 46 to the slave bootstrap interface modules 24. The bootstrap strobe signal carried on line 42 denotes the beginning of an address/data word pair. The signals are latched at the slave bootstrap interface modules 24 according to the bootstrap clock signal carried on line 42.

Similar to the bootstrap bus 20, each bootstrap interface module may comprise a minimum of hardware, each having three registers: a bootstrap control register 50, an address/command register 52, and a data register 54. These registers interact with a bootstrap state machine 56 within each module that will be further described herein.

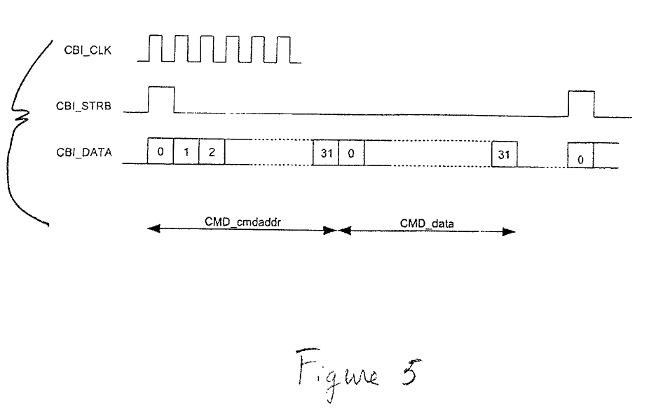

Referring now to FIG. 5, a timing diagram for the signals on the bootstrap bus 20 is illustrated. The clock strobe signal signifies the start of the transmission of a 64-bit command/address and data signal 32-bit word pair. Both the command/address signal and the bootstrap data signal are stable on the falling edge of the bootstrap clock signal. The master bootstrap interface module 22 sets up the bootstrap data signal and the address/command signal on the rising edge of the bootstrap clock signal. Similarly, the slave bootstrap interface module 24 reads the bootstrap data signal the address/command signal on the falling edge of the bootstrap clock signal. Note that the choice of either a rising or falling edge clock signal is arbitrary and may be altered.

The bootstrap interface module 24 in the slave processors may read and write to control registers coupled to the system bus 28. These control registers include the control and configuration registers of the memory controller (such as MEM_REQ_EN and MEM_BA register discussed earlier). The master processor 12 would first use its bootstrap interface module 22 and the bootstrap bus 20 to send commands to configure the relevant configuration registers of the slave processor memory controller.

The bootstrap bus 20 supports 3 commands for the master processor 12 to: 1) write to a slave processor's internal control registers, 2) write to a slave processor's external memory and 3) command the slave bootstrap interface module 24 to suspend operation (CBI_finish command).

Typically the master processor 12 would use the control register write command to configure the memory controller's configuration registers such as the MEM_BA registers and the registers storing the IN_CLK and SD_CLK delays in each slave processor. Then it will use the memory write command to write the boot code into the external memory (typically an SDRAM device) of each slave processor. It will then use the control register write command to set the MEM_REQ_EN register in slave processor to all 1's followed by a CBI_finish command Finally, note that the bootstrap bus 20 is a point-to-multi-point bus with respect to transmission from the master to the slave processors. In many instances, the slaves may all be identical, in which case each requires the same boot code and delay values. For such a multiple processor system, the master bootstrap interface module 22 need only broadcast simultaneously to all slave processors at once. However, there are circumstances, such as where the slave processors are different, wherein the master bootstrap module 22 must transmit to a particular slave bootstrap interface module 24. Thus, the command/address signal preferably has a bit field dedicated to a slave select signal that may either select all the slaves (broadcast mode) or a particular slave bootstrap interface module 24. An example configuration for these bit fields in the address/command register 52 is as follows:

| Bit Field | Name | R/W | Default | Description |
|---|---|---|---|---|
| 31:28 | Slave_sel | R/W | 0 | Slave device select |
| | | | | 0: broadcast message— |
| | | | | for all slave devices |
| | | | | 1: message for slave 1 |
| | | | | 2: message for slave 2 |
| | | | | 3: message for slave 3 |
| | | | | 4-15: reserved |
| 27:2 | Addr1 | R/W | 0 | Bits[27:2] of the control |
| | | | | register address or memory. |
| | | | | Automatically post increment by |
| | | | | 1 after every transmit. |
| 1:0 | Command | R/W | 0 | ′b00: Memory_write |
| | | | | ′b01: control register_write |
| | | | | ′b10: finish |
| | | | | ′b11: reserved |

After properly seeding the SDRAM 62 devices of slave processors using memory write commands, the master bootstrap interface module 22 will issue a finish command. The finish command puts the slave bootstrap interface module 24 into a suspend mode to save power. Note that the address/command register 52 may be configured to automatically post increments by 1 in the address field to facilitate sequentially writing data words to contiguous memory locations during the memory seeding process.

The control register 50 in the bootstrap interface module allows the clock speed of the bootstrap bus 20 to be set as well as status information indicating the state of the bootstrap interface module. In one embodiment, the clock speed of the bootstrap bus 20 can be set to ¼^{th} or ⅛^{th} of the system clock speed of between of 100 MHz and 133 MHz. By setting the clock speed of the bootstrap bus 20 to such speeds, ample time is provided for the completion of a particular write operation before the next 64-bit address/command and data word is sent on the bootstrap bus 20. The status bits indicate whether the bootstrap interface module is busy transmitting to the slave processor.

The bit-field contents for the control register 50 may thus be as follows:

| Bit Field | Name | R/W | Default | Description |
|---|---|---|---|---|
| 31:30 | Istate | R/W | ′b11 | ′b00: run |
| | | | | ′b01: reserved, |
| | | | | ′b10: reset. |
| | | | | ′b11: halt (default) |
| 29:2 | Reserved | R | 0 | |
| 1 | clkdiv | R/W | 0 | 0: CBI_CLK rate is system |
| | | | | clock/4 |
| | | | | 1: CBI_CLK rate is system |
| | | | | clock/8 |
| 0 | busy | R | 0 | 0: CBI not transmitting |
| | | | | 1: CBI transmitting on |
| | | | | CBI_DATA |

The data register 54 in the master bootstrap interface module 22 contains data to be written to the slave processor. The software in the master processor 12 will normally first write the appropriate value into the command/address register 52 followed by a write to the data register 54. Every write to the data register 54 will trigger the master bootstrap interface module 22 to start the transmit operation. The transmit operation simply involves sequentially shifting the data bits in the command/address 52 and data registers 54 onto the bootstrap data line 46 in the bootstrap bus 20 bit by bit. Every transmit operation is started with the master bootstrap interface module 22 asserting the strobe signal (CBI_STRB) for one clock cycle.

In the slave bootstrap interface module 24, two sets (only one set is illustrated) of command/address 52 and data registers 54 may be used to receive the data transmitted by the master processor 12. These two register sets are used in a “ping-pong” fashion. Such an embodiment allows the slave bootstrap interface module 24 to receive data over the bootstrap bus 20 while a previously-transmitted address/command and data word pair are being executed.

At a bootstrap clock rate of 25 MHz and a system clock rate of 100 MHz, it will take 256 system clock cycles for a new set of address/command and data word pair to arrive at the slave bootstrap interface module. This period of system clock cycles typically provides ample time for the completion of the previous memory or control register write operation.

The bootstrap state machines 56 are quite simple. For example, the main function of the state machine 56 in the master bootstrap interface module 22 is to shift the data in the address/command register 52 and the data register 54 onto the data signal line 46. For a slave device, the primary function of the state machine 56 is to shift the serial data received on the data signal line 46 into its address/command register 52 and data register 54 and execute the commands discussed with respect to the address/command register 52.

As discussed earlier, the master processor uses the control register write command to set the values of IN_CLK and SD_CLK in a slave processor's memory controller 30. Note that, a priori, the master processor 12 cannot know with certainty what the values it should command for the IN_CLK, SD_CLK pair used by a slave's memory controller 30. In one embodiment, the master processor may simply assume the same values used by its memory controller 30 should be used for the transmitted IN_CLK, SD_CLK pair. Indeed, the master processor may have selected the IN_CLK, SD_CLK pair for its memory controller according to the edge avoidance algorithm as set forth in copending U.S. application “Automatic Configuration of Delay Parameters in a Dynamic Memory Controller.” Assuming the memory controller layouts and routing between the respective SDRAM devices 62 are similar, the use of the same IN_CLK, SD_CLK pair may be a good solution. However, making such assumptions may not be appropriate. Moreover, the routing and layouts for the slave processors may differ, requiring a different set of delays than that used by the master's memory controller. Thus, the selection of a IN_CLK, SD_CLK pair for the slave processors by the master processor 12 according to the edge avoidance algorithm will now be described.

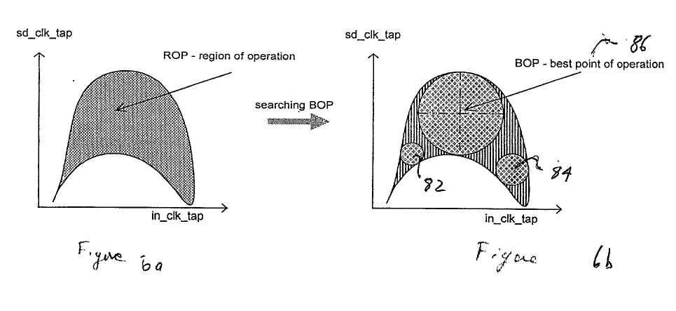

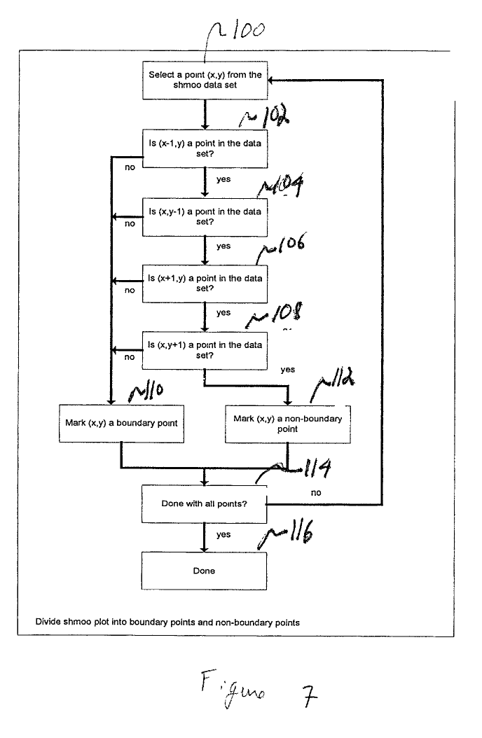

Note that the range of tap values for IN_CLK and SD_CLK may be normalized between 0 and 1, where a value of 1 represents the system clock period. The master processor commands its memory controller 30 to search the normalized IN_CLK and SD_CLK value space between 0 and 1 to find IN_CLK and SD_CLK pairs that produce an acceptable memory controller 30 performance. The IN_CLK and SD_CLK pairs that provide acceptable performance produce a shmoo plot as shown in FIG. 6a. The suitable IN_CLK and SD_CLK pairs form a region of operation. In the edge avoidance algorithm, this region of operation is divided into boundary and non-boundary points. Boundary points are those points within the shmoo plot that form the boundary of the region of operation. Note that as used herein, “within the shmoo plot” shall denote IN_CLK, SD_CLK pairs achieving acceptable SDRAM operation by a memory controller configured according to these IN_CLK, SD_CLK pairs. The test of whether acceptable SDRAM operation occurs is determined differently in a master processor 12 as compared to the slave processors. For example, the master processor 12 could command its memory controller 30 to write a unique test pattern, e.g., 0×cafe5a01 to its SDRAM device 62. By comparing what was written to the SDRAM device 62 with what is then read back by the memory controller 30, a particular IN_CLK, SD_CLK pair is tested. IF what was written is the same as what is read back from memory, the IN_CLK, SD_CLK pair is within the shmoo plot.

However, such a test cannot be conducted for slave processors in the master/slave architecture 10 of FIG. 1. The bootstrap bus 20 is not a two-way bus such that there is no way for the master processor 12 to know that a slave's memory controller 30 has performed successfully with a particular IN_CLK, SD_CLK pair. Instead, the test of whether an IN_CLK, SD_CLK pair is within the shmoo plot for a slave's memory controller can only be determined by whether the particular slave processor can successfully boot using the transferred boot code. A slave processor indicates to the master processor 12 that has booted successfully by signaling over an operating interface 60 that it is operating normally.

The master processor 12 uses the control register write command to command a particular IN_CLK, SD_CLK pair to sample the shmoo plot. Various methods can be used to search the normalized IN_CLK and SD_CLK tap value space between 0 and 1 for each variable to find acceptable values. For example, using normalized values, IN_CLK could be set to 0 and SD_CLK tested at discrete points between 0 and 1. Then IN_CLK would be incremented and SD_CLK varied again. This would be repeated until IN_CLK equaled 1 in a nested-do-loop-type method. Clearly, minimizing the amounts of increments in IN_CLK and SD_CLK used more accurately samples the region of operation. However, excessive sampling introduces delay in completing the testing. Sampling each tap value at least 20 times at equal increments between 0 and 1, producing a shmoo plot sampled at 400 points typically provides good results.

The edge avoidance algorithm proceeds by determining for a selected point within the non-boundary set, the distances to the points in the boundary set. From these distances, the minimum distance is selected. Effectively, the minimum distance corresponds to the radius of the largest circle that can be drawn about the selected point. The minimum distances for all the points in the non-boundary set are calculated and the maximum such minimum distance determined. The point associated with this maximum minimum distance is located the furthest from the boundary values because about this point the circle of largest radius can be drawn within the shmoo plot.

For example, FIG. 3b shows three points 82, 84, and 86 within the shmoo plot. At point 82, a comparably small circle fits within the shmoo plot. At point 84, a larger circle fits within the shmoo plot. Because this circle is larger than the one about point 82, it is more robust to changes in operating conditions that might shift an acceptable value for IN_CLK and SD_CLK into a failing value. At point 86, the largest circle exists that can fit within the shmoo plot. Thus, point 86 is the furthest point from the edge of the shmoo plot, making point 86 the most robust to changes in operating conditions. These changes in operating conditions include changes in temperature and aging that would affect the transmission parameters (e.g., capacitance) of the data bus 70 and the line carrying the SDRAM clock 68.

Turning now to FIG. 7, an algorithm for testing whether a point in the shmoo plot is a boundary point is illustrated. The algorithm begins with a shmoo point (x,y) selection at step 100. The next four steps in the algorithm test the four Cartesian points about this (x,y) location. Thus, whether points (x−1,y), (x,y−1), (x+1,y), and (x,y+1) are within the schmoo plot are tested at steps 102, 104, 106, and 108, respectively. Should any of these tests fail, the point is marked as a boundary point at step 110. Otherwise, the point is marked as a non-boundary point at step 112. Whether all the points within the shmoo plot have been tested is determined at step 114. If points remain to be tested, one of the remaining points is selected at step 100 and the algorithm repeats. if no points remain to be tested, the algorithm exits at step 116.

In addition, rather than select an IN_CLK, SD_CLK pair based upon having the maximum distance from the boundary points, other criteria could be used. For example, any point satisfying a fixed threshold, e.g., 75% of this maximum distance could be selected.

A sample bootstrap procedure may thus be summarized as follows:

1. The master processor 12 comes out of reset at power-up and boots from the ROM device normally.

2. The slave processors come out of reset at power-up and identify themselves as slaves. The slave bootstrap interface modules 24 configure their memory controllers 30 to deny processor memory requests. Because the processor memory request are denied, when the slave CPUs come out of reset and request their first instruction from ROM, no memory fetch is returned. The slave CPUs will then stall at this instruction fetch.

3. The master bootstrap interface module 22 sets the MEM_BA2 and MEM_BA7 registers in the slave memory controllers 30 to reflect a base address of 0×0000_{—}0000 and 0×1fc0_{—}0000, respectively and selects a IN_CLK, SD_CLK delay value pair.

4. The master bootstrap interface module transfers the boot image to the slave's SDRAM devices using the memory write command. The contents of the boot code designated for 0×1fc0_{—}0000 through 0×1fc0_{—}007f are written to 0×0000_{—}0000 through 0×0000_{—}007f. These addresses are mapped to the same memory cells in the SDRAM devices. The slave's memory controllers transfer the boot code using the selected IN_CLK, SD_CLK delay value pair.

5. The master bootstrap interface module sets the MEM_REQ_EN registers in the slave memory controllers to 1's and issues the finish command to halt the slave bootstrap interface modules.

6. If the SD_CLK and IN_CLK values selected by the master processor to configure the slave's memory controllers are within the shmoo plot, the slave processors may now operate normally (processor memory requests are honored) and begin fetching the first “ROM” instruction at 0×1fc0_{—}0000 from the SDRAM devices. The slave processors can then boot.

7. The slave processors 12, 14, and 16 may then signal over the HDLC interface 60 that they are running normally.

8. If the slave processors did not boot successfully, they cannot signal over the HDLC interface 60. Instead, a timer expires at the master processor, whereupon a failed boot is assumed for the selected IN_CLK, SD_CLK delay value pair. The master processor then resets the slave processors.

9. Steps 3 through 8 are repeated for remaining IN_CLK, SD_CLK delay value pairs to properly sample the shmoo plot.

10. The master processor performs the edge avoidance algorithm to locate an optimal IN_CLK, SD_CLK delay value pair within the shmoo plot.

11. After resetting the slave processors, and rebooting the slave processors with the optimal IN_CLK, SD_CLK delay value pair, the master bootstrap interface module 22 shuts down the bootstrap bus 20 by tri-stating its pins.

Note the advantages provided by this bootstrap procedure. No hardware changes are necessary in the CPU cores—they act as if they are still coupled to both a ROM and an SDRAM device for an ordinary boot procedure. The bootstrap bus 20 requires only three pins for each processor. Similarly, the hardware required by the bootstrap interface modules is minimal. Moreover, no manual testing of the delay parameters for the slave processor's memory controllers is required.

Although the invention has been described with reference to particular embodiments, the description is only an example of the invention's application and should not be taken as a limitation. For example, although described with respect to MIPS-based processors, the invention is equally applicable to other types of processors. Consequently, various adaptations and combinations of features of the embodiments disclosed are within the scope of the invention as defined by the following claims.

We claim:

1. A method of determining optimal delay for a multiprocessor system having a master processor and at least one slave processor, wherein each processor includes a memory controller associated with a SDRAM device, the memory controller of the master processor also being associated with a ROM device for storing boot code; each memory controller being coupled to a bus and communicating with its SDRAM device according to a first delay and a second delay;
defining a set having a plurality of delay pairs, each delay pair corresponding to a first delay value and a second delay value
(a) configuring the memory controller of the slave processor with a selected delay pair;
(b) transferring boot code from the ROM device to the memory controller of the slave processor using the bootstrap bus;
(c) testing whether the slave processor will initialize with the transferred boot code to determine if the delay pair is a successful delay pair;
(d) repeating acts (a) through (c) for the remaining delay pairs, thereby determining a set of successful delay pairs;
(e) dividing the set delay pairs into a boundary set and a non-boundary set; and
(f) selecting an optimal delay pair from the non-boundary set as determined by its relationship to the delay pairs in the boundary set.

2. The method of claim 1, wherein act (f) comprises:
(g) determining the minimum distance from each delay pair within the boundary set to delay pairs within the non-boundary set; and
(h) selecting the delay pair from act (g) having the largest minimum distance.

3. The method of claim 3, wherein act (b) includes mapping the transferred boot code to a first address space in the SDRAM device associated with the slave processor's memory controller.

4. The method of claim 3, further comprising the step of:
if the slave processor initializes in act (c), receiving processor memory requests at the memory controller of the initialized slave processor, the memory controller mapping the processor memory request to a second address space in its SDRAM device.

5. The method of claim 4, wherein the processors are MIPS-based processors.

6. The method of claim 1, wherein act (a) comprises transmitting a command from the master processor to the slave processor over the bus.

7. The method of claim 6, wherein act (a) comprises:
transmitting a strobe on the bus indicating the beginning of the command; and
transmitting a clock signal on the bus, wherein the transmitting the command occurs serially according to the clock signal.

8. The method of claim 7, wherein the command configures a control register in the memory controller of the slave processor to use the selected delay pair.
